(19) United States
(12) Patent Application Publication
(10) Pub. No.: US 2025/0350093 A1
(43) Pub. Date: Nov. 13, 2025

(54) SEMICONDUCTOR LASER

(71) Applicant: HAMAMATSU PHOTONICS K.K., Hamamatsu-shi (JP)

(72) Inventors: Masahiro HITAKA, Hamamatsu-shi (JP); Yutaka TAKAGI, Hamamatsu-shi (JP)

(73) Assignee: HAMAMATSU PHOTONICS K.K., Hamamatsu-shi (JP)

(21) Appl. No.: 19/186,919

(22) Filed: Apr. 23, 2025

(30) Foreign Application Priority Data
May 9, 2024 (JP) 2024-076661

(51) Int. Cl. H01S 5/042; H01S 5/22; H01S 5/227; H01S 5/343

(52) U.S. Cl. CPC H01S 5/04256; H01S 5/2222; H01S 5/227; H01S 5/34313; H01S 5/34346

(57) ABSTRACT

Provided is a semiconductor laser including: a semiconductor substrate; a semiconductor lamination portion laminated on a surface of the semiconductor substrate; and a first electrode and a second electrode. The semiconductor lamination portion includes an active layer, a first cladding layer located on the semiconductor substrate side with respect to the active layer, and a second cladding layer located on a side opposite to the semiconductor substrate with respect to the active layer, each of the first cladding layer and the second cladding layer includes an n-type cladding layer, one cladding layer of the first cladding layer and the second cladding layer further includes a p-type cladding layer located between the n-type cladding layer and the active layer.

### TECHNICAL FIELD

The present disclosure relates to a semiconductor laser.

### BACKGROUND

Japanese Unexamined Patent Publication No. 2007-123837 discloses a semiconductor laser element including an active layer including an optical guide layer, and an n-type cladding layer and a p-type cladding layer disposed with the active layer interposed therebetween. The p-type cladding layer has a thickness of approximately 1.5 μm.

### SUMMARY

In the above-described semiconductor laser, optical absorption in the p-type cladding layer becomes a problem. Particularly, optical absorption in an eye-safe wavelength region including a wavelength of 1.4 μm or more was a problem. With respect to this, when reducing the thickness of the p-type cladding layer, the optical absorption in the p-type cladding layer can be suppressed, but when reducing the thickness of the p-type cladding layer, there is a concern that optical confinement between the n-type cladding layer and the p-type cladding layer may be difficult.

Here, an object of the present disclosure is to provide a semiconductor laser capable of suppressing optical absorption while enabling optical confinement.

A semiconductor laser according to an aspect of the present disclosure is [1] “A semiconductor laser including: a semiconductor substrate; a semiconductor lamination portion laminated on a surface of the semiconductor substrate; and a first electrode and a second electrode, in which the semiconductor lamination portion includes an active layer, a first cladding layer located on the semiconductor substrate side with respect to the active layer, and a second cladding layer located on a side opposite to the semiconductor substrate with respect to the active layer, each of the first cladding layer and the second cladding layer includes an n-type cladding layer, one cladding layer of the first cladding layer and the second cladding layer further includes a p-type cladding layer located between the n-type cladding layer and the active layer, the first electrode and the second electrode are electrically connected to each other via the other cladding layer of the first cladding layer and the second cladding layer, the active layer, and the p-type cladding layer, and the thickness of the p-type cladding layer is smaller than the thickness of the n-type cladding layer in the one cladding layer”.

In the semiconductor laser, the thickness of the p-type cladding layer in the one cladding layer of the first cladding layer and the second cladding layer is smaller than the thickness of the n-type cladding layer in the one cladding layer. According to this, for example, as compared with a case where the entirety of the one cladding layer is set as the p-type cladding layer, the thickness of the p-type cladding layer is further reduced, and thus optical absorption in the p-type cladding layer can be suppressed. In addition, the one cladding layer includes the n-type cladding layer in addition to the p-type cladding layer. According to this, it is possible to secure the thickness of the entirety of the one cladding layer. According to this, appropriate optical confinement between the first cladding layer and the second cladding layer is enabled. Accordingly, according to the semiconductor laser, it is possible to suppress the optical absorption while enabling the optical confinement.

The semiconductor laser according to the aspect of the present disclosure may be [2] “The semiconductor laser according to [1], further including: a p-type burying layer that is in contact with the p-type cladding layer in a direction intersecting a lamination direction in the semiconductor lamination portion, in which the first electrode is provided on a surface of the p-type burying layer on a side opposite to the semiconductor substrate”. In this case, since the p-type burying layer and the p-type cladding layer are in contact with each other, heat generated in the active layer is dissipated via the p-type burying layer. Accordingly, according to the semiconductor laser, it is possible to improve a heat dissipation property.

The semiconductor laser according to the aspect of the present disclosure may be [3] “The semiconductor laser according to [2], in which a groove recessed toward the active layer is formed in a surface of the second cladding layer on a side opposite to the active layer”. For example, in a case where the p-type burying layer is formed across the surface of the second cladding layer, it is possible to reduce a contact area between the p-type burying layer and the second cladding layer by forming the groove in the surface of the second cladding layer as described above. In this case, a current path from the p-type burying layer in the second cladding layer is narrowed, and thus a leakage current can be suppressed.

The semiconductor laser according to the aspect of the present disclosure may be [4] “The semiconductor laser according to [1], in which a surface of the p-type cladding layer on a side opposite to the semiconductor substrate includes an exposed region that is exposed from the semiconductor lamination portion, and the first electrode is provided in the exposed region”. In this case, as compared with a case where the p-type burying layer is formed and the first electrode is provided in the p-type burying layer, a configuration of the semiconductor laser is more simplified, and the semiconductor laser can be easily formed.

The semiconductor laser according to the aspect of the present disclosure may be [5] “The semiconductor laser according to any one of [1] to [4], in which the semiconductor substrate consists of an n-type semiconductor”. In this case, as compared with a case where the semiconductor substrate consists of a p-type semiconductor, the optical absorption can be further suppressed. In addition, in this case, it is possible to establish contact with the n-type cladding layer via the semiconductor substrate.

The semiconductor laser according to the aspect of the present disclosure may be [6] “The semiconductor laser according to any one of [1] to [5], further including: a third electrode that is electrically connected to the first electrode via the n-type cladding layer in the one cladding layer and the p-type cladding layer”. In this case, it is possible to increase a built-in potential at the pn junction by applying a reverse bias voltage with respect to the pn junction formed between the n-type cladding layer in the one cladding layer and the p-type cladding layer by the first electrode and the third electrode. According to this, leakage of carriers from the active layer can be reliably suppressed.

The semiconductor laser according to the aspect of the present disclosure may be [7] “The semiconductor laser according to any one of [1] to [6], in which the thickness of the p-type cladding layer is larger than the thickness of a portion, which is formed inside of the p-type cladding layer, in a depletion layer formed due to a pn junction formed between the n-type cladding layer in the one cladding layer and the p-type cladding layer. In this case, it is possible to reliably secure a region that does not become the depletion layer with respect to the p-type cladding layer.

The semiconductor laser according to the aspect of the present disclosure may be [8] “The semiconductor laser according to any one of [1] to [7], in which the thickness of the p-type cladding layer is ½ or less of the thickness of the n-type cladding layer in the one cladding layer”. In this case, it is possible to reliably suppress the optical absorption.

The semiconductor laser according to the aspect of the present disclosure may be [9] “The semiconductor laser according to any one of [1] to [8], in which the one cladding layer is a first cladding layer”. In this case, the above-described effect can be appropriately exhibited.

The semiconductor laser according to the aspect of the present disclosure may be “The semiconductor laser according to any one of [1] to [8], in which the one cladding layer is a second cladding layer”. In this case, the above-described effect can be appropriately exhibited. According to the aspect of the present disclosure, it is possible to provide a semiconductor laser capable of suppressing optical absorption while enabling optical confinement.

### BRIEF DESCRIPTION OF THE DRAWINGS

FIG. 1 is a cross-sectional view of a semiconductor laser according to a first embodiment.

FIG. 2 is a graph illustrating a relationship between the thickness of a depletion layer and a carrier concentration of an n-type cladding layer.

FIG. 3 is a graph illustrating a relationship between the thickness of the depletion layer and a carrier concentration of a p-type cladding layer.

FIG. 4 is a view illustrating carrier blocking by a built-in potential.

FIG. 5 is a cross-sectional view of a semiconductor laser according to a second embodiment.

FIG. 6 is a cross-sectional view of a semiconductor laser according to a third embodiment.

FIG. 7 is a cross-sectional view of a semiconductor laser according to a fourth embodiment.

FIG. 8 is a cross-sectional view of a semiconductor laser according to a first modification example.

FIG. 9 is a cross-sectional view of a semiconductor laser according to a second modification example.

### DETAILED DESCRIPTION

Hereinafter, an embodiment of a semiconductor integrated element according to the present disclosure will be described in detail with reference to the accompanying drawings. Note that, in description of the drawings, the same reference numeral will be given to the same element, and redundant description thereof will be omitted. Hereinafter, a semiconductor having an n-type conductivity type may be described as an “n-type semiconductor”, and a semiconductor having a p-type conductivity type may be described as a “p-type semiconductor”.

### First Embodiment

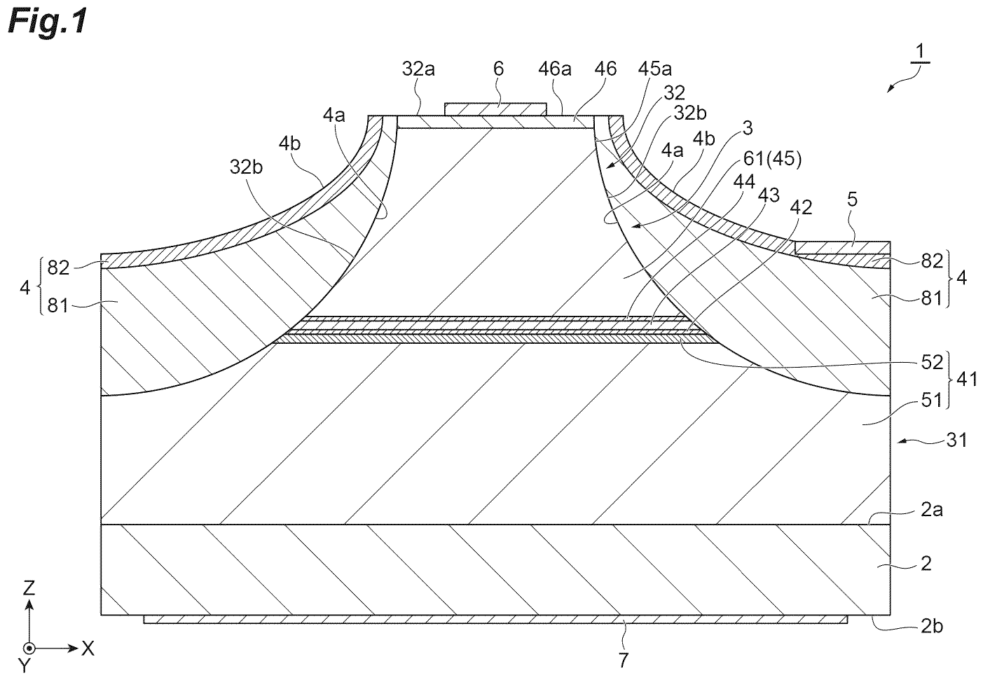

FIG. 1 is a cross-sectional view of a semiconductor laser according to a first embodiment. A semiconductor laser 1 shown in FIG. 1 oscillates laser light having a wavelength of approximately 1550 nm as an example. As shown in FIG. 1, the semiconductor laser 1 includes a semiconductor substrate 2, a semiconductor lamination portion 3, a p-type burying layer 4, a first electrode 5, a second electrode 6, and a third electrode 7.

The semiconductor substrate 2 has a front surface 2a, and a rear surface 2b on a side opposite to the front surface 2a. Hereinafter, a direction intersecting the front surface 2a and the rear surface 2b is set as a Z-direction. In addition, directions along the front surface 2a and the rear surface 2b and intersecting each other (orthogonal to each other) are set as an X-direction and a Y-direction.

The semiconductor substrate 2 consists of an n-type semiconductor. The semiconductor substrate 2 is formed by, for example, a material containing InP. As an example, the semiconductor substrate 2 consists of InP. A carrier concentration of the semiconductor substrate 2 is, for example, approximately 3.0×10¹⁸ (cm⁻³). The thickness of the semiconductor substrate 2 is, for example, approximately 3500 nm.

The semiconductor lamination portion 3 is laminated on the front surface 2a of the semiconductor substrate 2. The semiconductor lamination portion 3 includes a base portion 31 and a mesa portion 32. The base portion 31 is formed on the front surface 2a of the semiconductor substrate 2. The mesa portion 32 is provided on a partial region of the base portion 31. The mesa portion 32 has a top surface 32a on a side opposite to the semiconductor substrate 2 and the base portion 31, and a side surface 32b that extends from the top surface 32a and reaches the base portion 31. The top surface 32a intersects (is orthogonal to) a lamination direction (Z-direction) of the semiconductor lamination portion 3. The side surface 32b is curved so that a width related to the X-direction of the mesa portion 32 gradually increases as approaching the base portion 31 from the top surface 32a along the lamination direction.

The semiconductor lamination portion 3 includes a first cladding layer 41, a guide layer 42, an active layer 43, a guide layer 44, a second cladding layer 45, and a contact layer 46 sequentially laminated on the front surface 2a of the semiconductor substrate 2. Accordingly, the first cladding layer 41 is located on the semiconductor substrate 2 side with respect to the active layer 43. In addition, the second cladding layer 45 is located on a side opposite to the semiconductor substrate 2 with respect to the active layer 43. The first cladding layer 41 and the second cladding layer 45 are cladding layers configured to confine light emitted from the active layer 43 in the guide layer 42, the active layer 43, and the guide layer 44 located between the first cladding layer 41 and the second cladding layer 45.

Here, the base portion 31 is formed by a part of the first cladding layer 41 on the semiconductor substrate 2 side. The mesa portion 32 is formed by a part of the first cladding layer 41 on a side opposite to the semiconductor substrate 2, the guide layer 42, the active layer 43, the guide layer 44, the second cladding layer 45, and the contact layer 46. That is, the first cladding layer 41 is formed across from the base portion 31 to the mesa portion 32.

One cladding layer of the first cladding layer 41 and the second cladding layer 45 includes a p-type cladding layer, and the other cladding layer does not include the p-type cladding layer (here, a p-type semiconductor layer). In this embodiment, the first cladding layer 41 is the one cladding layer including a p-type cladding layer 52. That is, the first cladding layer 41 includes an n-type cladding layer 51 and the p-type cladding layer 52 sequentially laminated on the front surface 2a of the semiconductor substrate 2. The n-type cladding layer 51 has the n-type conductivity type. The n-type cladding layer 51 is joined to the semiconductor substrate 2 and the p-type cladding layer 52. The n-type cladding layer 51 is formed by, for example, a material containing InP. As an example, the n-type cladding layer 51 consists of InP. A carrier concentration of the n-type cladding layer 51 is, for example, 1.0×10¹⁷ (cm⁻³). The thickness of the n-type cladding layer 51 is, for example, approximately 1500 nm. The n-type cladding layer 51 is different from the p-type cladding layer 52 to be described later in the conductivity type, but is formed by a material having a refractive index similar to that of the p-type cladding layer 52.

The p-type cladding layer 52 has the p-type conductivity type. The p-type cladding layer 52 is joined to the n-type cladding layer 51 and the guide layer 42. The p-type cladding layer 52 is formed by, for example, a material containing InP. As an example, the p-type cladding layer 52 consists of InP. A carrier concentration of the p-type cladding layer 52 is, for example, 1.0×10¹⁸ (cm⁻³). The thickness of the p-type cladding layer 52 is, for example, approximately 100 nm. That is, the thickness of the p-type cladding layer 52 is smaller than the thickness of the n-type cladding layer 51. As an example, the thickness of the p-type cladding layer 52 is ½ or less of the thickness of the n-type cladding layer 51, and is further 1/10 or less of the thickness of the n-type cladding layer 51.

As described above, in this embodiment, the n-type cladding layer 51 and the p-type cladding layer 52 are joined to each other. According to this, a pn-junction is formed between the n-type cladding layer 51 and the p-type cladding layer 52. In addition, a depletion layer formed due to the pn junction is formed between the n-type cladding layer 51 and the p-type cladding layer 52. Note that, “between the n-type cladding layer 51 and the p-type cladding layer 52” stated here means “between a surface of the n-type cladding layer 51 on a side opposite to the p-type cladding layer 52 and a surface of the p-type cladding layer 52 on a side opposite to the n-type cladding layer 51”. Accordingly, the depletion layer is formed across the inside of the n-type cladding layer 51 and the inside of the p-type cladding layer 52, but here, it is described that the depletion layer is formed between the n-type cladding layer 51 and the p-type cladding layer 52. As to be described later, in a state in which a voltage is not applied, in a case where the carrier concentration of the n-type cladding layer 51 is 1.0×10¹⁸ (cm⁻³) or less, and the carrier concentration of the p-type cladding layer 52 is approximately 1.0×10¹⁸ (cm⁻³), the thickness of a portion of the depletion layer, which is formed inside the p-type cladding layer 52, is at most approximately 30 nm. Accordingly, in a state in which a voltage is not applied, the thickness of the p-type cladding layer 52 is larger than the thickness of the portion, which is formed inside the p-type cladding layer 52, in the depletion layer.

The guide layer 42 is a non-doped layer that is not doped. The guide layer 42 may have the n-type conductivity type. The guide layer 42 is joined to the p-type cladding layer 52 and the active layer 43. The guide layer 42 is formed by, for example, a material containing InAlGaAs. As an example, the guide layer 42 consists of InAlGaAs. A carrier concentration of the guide layer 42 is, for example, approximately 5.0×10¹⁶ (cm⁻³). The thickness of the guide layer 42 is approximately 50 nm.

The active layer 43 is a non-doped layer that is not doped. The active layer 43 may have the n-type conductivity type. The active layer 43 is joined to the guide layer 42 and the guide layer 44. For example, the active layer 43 has a multiple quantum well structure including a well layer and a barrier layer. The well layer of the active layer 43 contains, for example, Inₓ₁Al_{y1}Ga_{1-x1-y1}As (provided that, x1>0, y1≥0, x1+y1<1). As an example, the well layer consists of InGaAs or InAlGaAs. The barrier layer of the active layer 43 contains, for example, Inₓ₂Al_{y2}Ga_{1-x2-y2}As (provided that, x2>0, y2>0, x2+y2≤1). As an example, the barrier layer consists of InAlAs or InAlGaAs. A carrier concentration of the active layer 43 is, for example, approximately 5.0×10¹⁶ (cm⁻³). The thickness of the active layer 43 is approximately 100 nm.

The guide layer 44 is a non-doped layer that is not doped. The guide layer 44 may have the n-type conductivity type. The guide layer 44 is joined to the active layer 43 and the second cladding layer 45. The guide layer 44 is formed by, for example, a material containing InAlGaAs. As an example, the guide layer 44 consists of InAlGaAs. A carrier concentration of the guide layer 44 is, for example, approximately 5.0×10¹⁶ (cm⁻³). The thickness of the guide layer 44 is approximately 50 nm.

The second cladding layer 45 has a surface 45a on a side opposite to the semiconductor substrate 2. The surface 45a includes a portion along the top surface 32a in the semiconductor lamination portion 3, and a part of the side surface 32b. The second cladding layer 45 includes an n-type cladding layer 61. That is, each of the first cladding layer 41 and the second cladding layer 45 includes an n-type cladding layer. In this embodiment, the second cladding layer 45 does not include a p-type cladding layer, and include only the n-type cladding layer 61. The n-type cladding layer 61 has the n-type conductivity type. The n-type cladding layer 61 (that is, the second cladding layer 45) is joined to the guide layer 44 and the contact layer 46. The n-type cladding layer 61 is formed by, for example, a material containing InP. As an example, the n-type cladding layer 61 consists of InP. A carrier concentration of the n-type cladding layer 61 is, for example, approximately 1.0×10¹⁸ (cm-3). The thickness of the n-type cladding layer 61 is, for example, approximately 1500 nm.

The contact layer 46 has the n-type conductivity type. The contact layer 46 is formed by, for example, a material containing InGaAs. As an example, the contact layer 46 consists of InGaAs. For example, a carrier concentration of the contact layer 46 is larger than 5.0×10¹⁸ (cm⁻³). The thickness of the contact layer 46 is, for example, approximately 150 nm. The contact layer 46 is joined to the second cladding layer 45 on one side of the Z-direction, and is exposed to the outside on the other side of the Z-direction. Accordingly, the contact layer 46 has a surface 46a on a side opposite to the semiconductor substrate 2. The surface 46a of the contact layer 46 is the top surface 32a of the mesa portion 32 in the semiconductor lamination portion 3.

The p-type burying layer 4 is formed on the side surface 32b of the mesa portion 32 to bury the mesa portion 32. The p-type burying layer 4 is in contact with the side surface 32b. The p-type burying layer 4 has a surface 4a that is in contact with the side surface 32b, and a surface 4b on a side opposite to the surface 4a. The surface 4b is a surface on a side opposite to the semiconductor substrate 2. The p-type burying layer 4 is formed across from the n-type cladding layer 51 of the first cladding layer 41 to the contact layer 46. Accordingly, the p-type burying layer 4 is in contact with the n-type cladding layer 51, the p-type cladding layer 52, the guide layer 42, the active layer 43, the guide layer 44, the n-type cladding layer 61 (that is, the second cladding layer 45), and the contact layer 46 on the surface 4a. In other words, the p-type burying layer 4 is in contact with the p-type cladding layer 52 in a direction intersecting the lamination direction in the semiconductor lamination portion 3. The surface 4b is formed along the side surface 32b of the semiconductor lamination portion 3.

The p-type burying layer 4 has the p-type conductivity type. The p-type burying layer 4 includes a first burying layer 81 and a second burying layer 82 sequentially formed on the side surface 32b of the semiconductor lamination portion 3. The first burying layer 81 has the surface 4a. The first burying layer 81 is formed by, for example, a material containing InP. As an example, the first burying layer 81 consists of InP. A carrier concentration of the first burying layer 81 is, for example, approximately 1.0×10¹⁸ (cm⁻³). The thickness of the first burying layer 81 is, for example, approximately 1500 nm. The second burying layer 82 has the surface 4b of the p-type burying layer 4. The second burying layer 82 is formed by, for example, a material containing InGaAs. As an example, the second burying layer 82 consists of InGaAs. For example, a carrier concentration of the second burying layer 82 is larger than 5.0×10¹⁸ (cm⁻³). The thickness of the second burying layer 82 is, for example, approximately 150 nm. The thickness of the p-type burying layer 4 is larger than the thickness of the p-type cladding layer 52. According to this, it is possible to stably perform formation of the first electrode 5 and wire connection with respect to the p-type burying layer 4. Note that, the above-described thicknesses of the p-type burying layer 4, the first burying layer 81, and the second burying layer 82 indicate thicknesses in the lamination direction at a position which is spaced apart from the top surface 32a to an outer side and at which the surface 4b of the p-type burying layer 4 is parallel to a surface orthogonal to the lamination direction.

As described above, in a case where the p-type burying layer 4 is configured in two layers by the first burying layer 81 and the second burying layer 82, it is possibility to improve the heat dissipation property while suppressing an increase in electrical resistance. That is, the first burying layer 81 and the second burying layer 82 are formed by the materials respectively containing InP and InGaAs with relatively high thermal conductivity, and thus the heat dissipation property can be improved. In addition, the second burying layer 82 is formed by the material containing InGaAs to which a material of the first electrode 5 to be described later is less likely to diffuse as compared with InP, and thus it is possible to suppress an increase in electrical resistance between the first electrode 5 and the second burying layer 82. Accordingly, in the p-type burying layer 4, it is possible to improve the heat dissipation property while suppressing an increase in electrical resistance.

Here, in a case of attempting to manufacture an ohmic electrode with a p-type semiconductor consisting of InP, an electrode containing AuZn is typically employed. However, there is a concern that AuZn of the electrode diffuses into the p-type semiconductor depending on a formation condition. As a result, there is a concern that the electrode becomes a Schottky electrode, and has an influence on laser characteristics. On the other hand, with respect to a p-type semiconductor containing InGaAs, an electrode that contains Ti, Au, or the like, and is less likely to diffuse can be used.

The first electrode 5 is provided on the surface 4b of the second burying layer 82 of the p-type burying layer 4. That is, the first electrode 5 is provided on the surface 4b of the p-type burying layer 4 on a side opposite to the semiconductor substrate 2. The first electrode 5 is formed by, for example, a material containing Ti and Au. The first electrode 5 is formed, for example, in a two-layer configuration including a Ti layer and an Au layer. In addition, the second electrode 6 is provided on the surface 46a of the contact layer 46. The second electrode 6 is formed by, for example, a material containing Ti and Au. The second electrode 6 is formed, for example, in a two-layer configuration including a Ti layer and an Au layer. The first electrode 5 and the second electrode 6 are electrically connected to each other via the second cladding layer 45, the active layer 43, and the p-type cladding layer 52. Specifically, the first electrode 5 and the second electrode 6 are electrically connected to each other via the p-type burying layer 4, the p-type cladding layer 52, the guide layer 42, the active layer 43, the guide layer 44, the n-type cladding layer 61, and the contact layer 46. According to this, it is possible to apply a voltage to the mesa portion 32 via the first electrode 5 and the second electrode 6.

The third electrode 7 is provided on the rear surface 2b of the semiconductor substrate 2. The third electrode 7 is formed by, for example, a material containing AuGe and Au. For example, the third electrode 7 is formed in a two-layer configuration including an AuGe layer and an Au layer. The third electrode 7 is electrically connected to the first electrode 5 via the n-type cladding layer 51 and the p-type cladding layer 52 in the first cladding layer 41. The third electrode 7 is an electrode configured to apply a reverse bias voltage by the first electrode 5 and the third electrode 7 with respect to the pn junction formed between the n-type cladding layer 51 and the p-type cladding layer 52. According to this, it is possible to increase a built-in potential at the pn junction, and leakage of carriers from the active layer can be reliably suppressed.

When operating the above-described semiconductor laser 1, a forward bias voltage is applied between the n-type cladding layer 61 and the p-type cladding layer 52 of the semiconductor lamination portion 3 by the first electrode 5 and the second electrode 6, and a reverse bias voltage is applied between the n-type cladding layer 51 and the p-type cladding layer 52 by the first electrode 5 and the third electrode 7. Specifically, a voltage is applied to the first electrode 5 and the third electrode 7 so that a voltage that is applied to the n-type cladding layer 61, a voltage that is applied to the p-type cladding layer 52, and a voltage that is applied to the n-type cladding layer 51 increase in this order. That is, a voltage is applied to the first electrode 5 and the third electrode 7 so that the voltage that is applied to the p-type cladding layer 52 is larger than the voltage that is applied to the n-type cladding layer 61, and the voltage that is applied to the n-type cladding layer 51 is larger than the voltage that is applied to the p-type cladding layer 52.

As described above, the depletion layer formed due to the pn junction is formed between the n-type cladding layer 51 and the p-type cladding layer 52. Hereinafter, description will be given of a verification result relating to the thickness of a portion, which is formed inside the p-type cladding layer 52, in the depletion layer. Note that, in the following description, the thickness of the portion, which is formed inside the p-type cladding layer 52, in the depletion layer may be referred to as “the thickness of the depletion layer of the p-type cladding layer 52”.

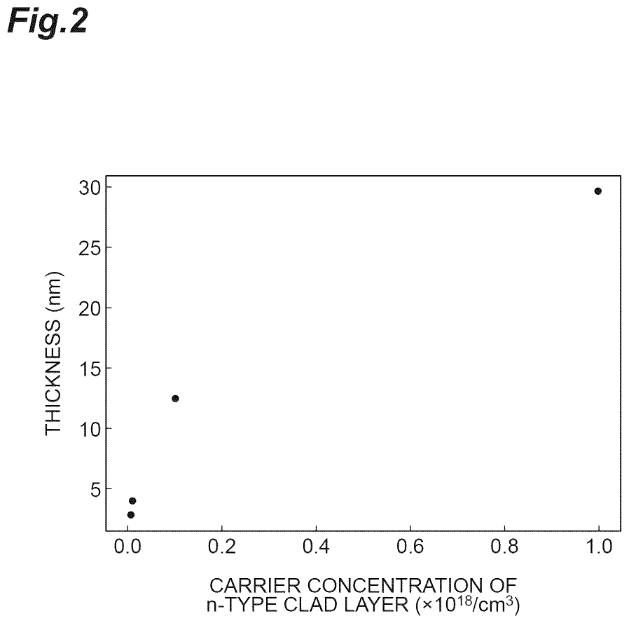

FIG. 2 is a graph showing a relationship between the carrier concentration (horizontal axis) of the n-type cladding layer 51 and the thickness (vertical axis) of the depletion layer of the p-type cladding layer 52. FIG. 2 shows a result in a case where the carrier concentration of the p-type cladding layer 52 is fixed to 1.0×10¹⁸ (cm⁻³), and the carrier concentration of the n-type cladding layer 51 is changed. From FIG. 2, it can be seen that the thickness of the depletion layer of the p-type cladding layer 52 also increases as the carrier concentration of the n-type cladding layer 51 increases. In addition, it can be seen that the thickness of the depletion layer is at most approximately 30 nm in a case where the carrier concentration of the n-type cladding layer 51 is 1.0×10¹⁸ (cm⁻³) or less. Accordingly, in this embodiment, since the carrier concentration of the n-type cladding layer 51 is 1.0×10¹⁸ (cm⁻³) or less, and the carrier concentration of the p-type cladding layer 52 is approximately 1.0×10¹⁸ (cm⁻³), the thickness of the depletion layer of the p-type cladding layer 52 is also at most approximately 30 nm. Accordingly, it can be seen that the thickness of the p-type cladding layer 52 may be larger than 30 nm to make the thickness of the p-type cladding layer 52 larger than the thickness of the depletion layer.

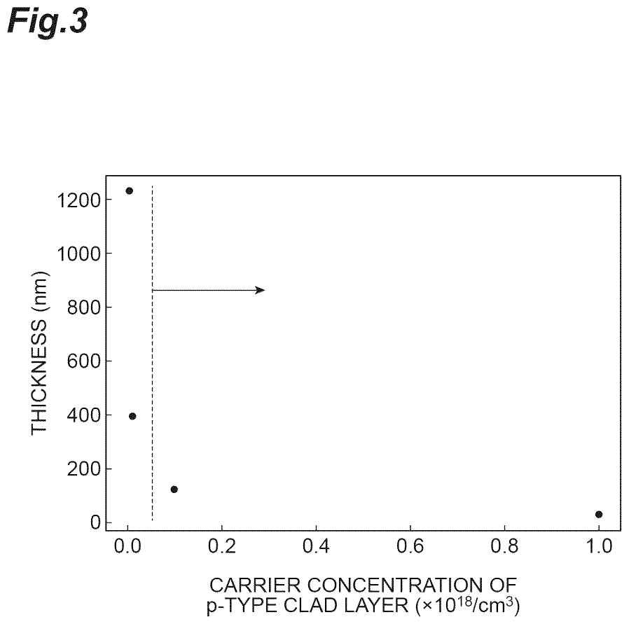

FIG. 3 is a graph showing a relationship between the carrier concentration (horizontal axis) of the p-type cladding layer 52 and the thickness (vertical axis) of the depletion layer of the p-type cladding layer 52. FIG. 3 shows a result in a case where the carrier concentration of the n-type cladding layer 51 is fixed to 1.0×10¹⁸ (cm⁻³), and the carrier concentration of the p-type cladding layer 52 is changed. From FIG. 3, it can be seen that the thickness of the portion formed inside the p-type cladding layer 52 increases as the carrier concentration of the p-type cladding layer 52 decreases. Note that, in FIG. 3, a minimum value (5.0×10¹⁶ (cm⁻³) of the carrier concentration in a case of using the p-type cladding layer 52 as a contact layer is indicated by a broken line. It can be seen that the thickness of the depletion layer of the p-type cladding layer 52 is at most approximately 400 nm in a case where the carrier concentration of the p-type cladding layer 52 is the minimum value. Accordingly, when the carrier concentration of the p-type cladding layer 52 is equal to or more than the minimum value, it is considered that the thickness of the depletion layer of the p-type cladding layer 52 is at most approximately 400 nm. Note that, as described above with reference to FIG. 2, in a case of this embodiment, since the carrier concentration of the p-type cladding layer 52 is 1.0×10¹⁸ (cm⁻³), the thickness of the depletion layer of the p-type cladding layer 52 is at most approximately 30 nm.

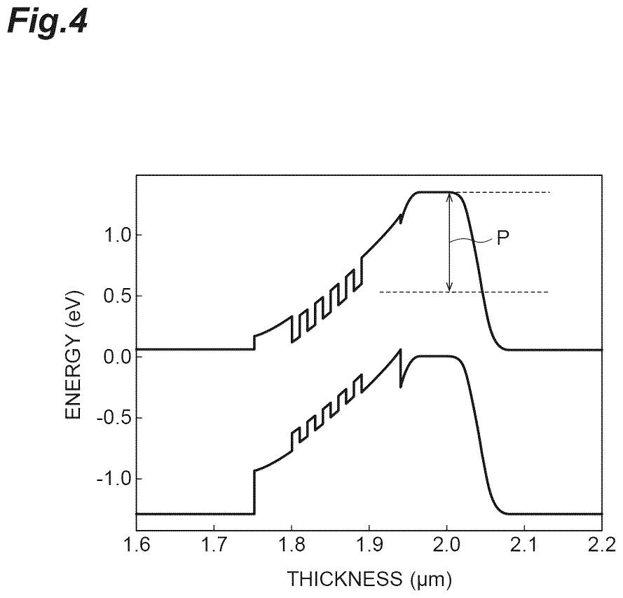

FIG. 4 is an energy band diagram for explaining the built-in potential due to the pn junction. The horizontal axis represents a position (the thickness) of the Z-direction in the semiconductor lamination portion 3, and the vertical axis represents energy. As shown in FIG. 4, a built-in potential P is generated by the depletion layer formed due to the pn junction. Leakage of carriers from the active layer 43 can be suppressed due to the built-in potential P.

As described above, in the semiconductor laser 1 according to this embodiment, the thickness of the p-type cladding layer 52 in the first cladding layer 41 is smaller than the thickness of the n-type cladding layer 51 in the first cladding layer 41. That is, in the semiconductor laser 1, the thickness of the p-type cladding layer 52 in the one cladding layer (in this embodiment, the first cladding layer 41) of the first cladding layer 41 and the second cladding layer 45 is smaller than the thickness of the n-type cladding layer 51 in the one cladding layer. According to this, for example, as compared with a case where the entirety of the first cladding layer 41 consists of the p-type cladding layer 52, in this embodiment, the thickness of the p-type cladding layer 52 is reduced, and the optical absorption in the p-type cladding layer 52 can be suppressed. In addition, in this embodiment, the first cladding layer 41 includes the n-type cladding layer 51 in addition to the p-type cladding layer 52. According to this, it is possible to secure the thickness of the entirety of the first cladding layer 41. According to this, appropriate optical confinement between the first cladding layer 41 and the second cladding layer 45 becomes possible. Accordingly, according to the semiconductor laser 1, it is possible to suppress the optical absorption while enabling the optical confinement.

Here, the n-type cladding layer 51 in the first cladding layer 41 is different from the p-type cladding layer 52 in a conductivity type, but is formed by a material having approximately the same refractive index as in the p-type cladding layer 52. Therefore, the n-type cladding layer 51 also serves as a cladding layer, and thus even though the p-type cladding layer 52 is thin, appropriate optical confinement between the first cladding layer 41 and the second cladding layer 45 becomes possible.

In addition, in the semiconductor laser 1 according to this embodiment, the pn junction is formed at a position between the n-type cladding layer 51 and the p-type cladding layer 52 in the first cladding layer 41, and the built-in potential P is generated due to the pn junction. According to this, leakage of carriers from the active layer 43 can be suppressed.

In addition, in the semiconductor laser 1 according to this embodiment, the p-type burying layer 4 is in contact with the p-type cladding layer 52. In this configuration, since the p-type burying layer 4 is in contact with the p-type cladding layer 52, heat generated in the active layer 43 is dissipated via the p-type burying layer 4. Accordingly, according to the semiconductor laser 1, it is possible to improve the heat dissipation property. Furthermore, the p-type burying layer 4 is in contact with the active layer 43. According to this, the heat generated in the active layer 43 is more effectively dissipated via the p-type burying layer 4. In addition, the thickness of the p-type burying layer 4 is larger than the thickness of the p-type cladding layer 52. According to this, it is possible to stably perform the formation of the first electrode 5 or the wire connection with respect to the p-type cladding layer 52.

In addition, in the semiconductor laser 1 according to this embodiment, the semiconductor substrate 2 consists of an n-type semiconductor. According to this, it is possible to further suppress the optical absorption as compared with a case where the semiconductor substrate 2 consists of a p-type semiconductor. That is, in a case where the semiconductor substrate 2 consists of the p-type semiconductor, there is a concern that the optical absorption by the semiconductor substrate 2 may occur in any of an edge emitting semiconductor laser and a surface emitting semiconductor laser. On the other hand, in this embodiment, since the semiconductor substrate 2 consists of the n-type semiconductor, it is possible to suppress the optical absorption by the semiconductor substrate 2. In addition, it is possible to establish contact with the n-type cladding layer 51 via the semiconductor substrate 2.

In addition, the semiconductor laser 1 according to this embodiment further includes the third electrode 7 that is electrically connected to the first electrode 5 via the n-type cladding layer 51 and the p-type cladding layer 52 in the first cladding layer 41. According to this, it is possible to increase the built-in potential at the pn junction by applying a reverse bias voltage with respect to the pn junction formed between the n-type cladding layer 51 and the p-type cladding layer 52 in the first cladding layer 41 by the first electrode 5 and the third electrode 7. According to this, leakage of carriers from the active layer 43 can be reliably suppressed.

Here, as a configuration of obtaining the effect of suppressing leakage of carriers from the active layer 43, a configuration of providing a carrier blocking layer, and a configuration of providing multiple quantum barrier (MQB) are known. In the configuration of providing the carrier blocking layer, the size of a potential barrier formed by the carrier blocking layer may not be sufficient. In addition, in the configuration of providing the multiple quantum barrier, since crystal interfaces increase, and thus there is a problem that crystallinity is poor, and a loss increases. On the other hand, in the semiconductor laser 1 according to this embodiment, as described above, since it is possible to increase the built-in potential at the pn junction by applying the reverse bias voltage by the first electrode 5 and the third electrode 7, leakage of carriers from the active layer 43 can be reliably suppressed, and the problem of an increase in loss due to an increase in crystal interface does not occur.

In addition, in the semiconductor laser 1 according to this embodiment, the thickness of the p-type cladding layer 52 is larger than the thickness of a portion, which is formed inside the p-type cladding layer 52, in the depletion layer formed due to the pn junction formed between the n-type cladding layer 51 and the p-type cladding layer 52 in the first cladding layer 41. According to this, it is possible to reliably secure a region that does not become the depletion layer with respect to the p-type cladding layer 52. Here, in the p-type cladding layer 52, the carrier concentration is set to be higher than the carrier concentration of the n-type cladding layer 51. Since the depletion layer has a characteristic of easily spreading out to a layer in which the carrier concentration is low, it is considered that the thickness of the portion, which is formed inside the p-type cladding layer 52, in the depletion layer does not spread out significantly even when the reverse bias voltage is applied.

In addition, in the semiconductor laser 1 according to this embodiment, the thickness of the p-type cladding layer 52 is ½ or less of the thickness of the n-type cladding layer in the one cladding layer. According to this, the optical absorption can be reliably suppressed.

In addition, in the semiconductor laser 1 according to this embodiment, the first cladding layer 41 between the first cladding layer 41 and the second cladding layer 45 is the one cladding layer. According to this, the above-described effect can be appropriately exhibited.

### Second Embodiment

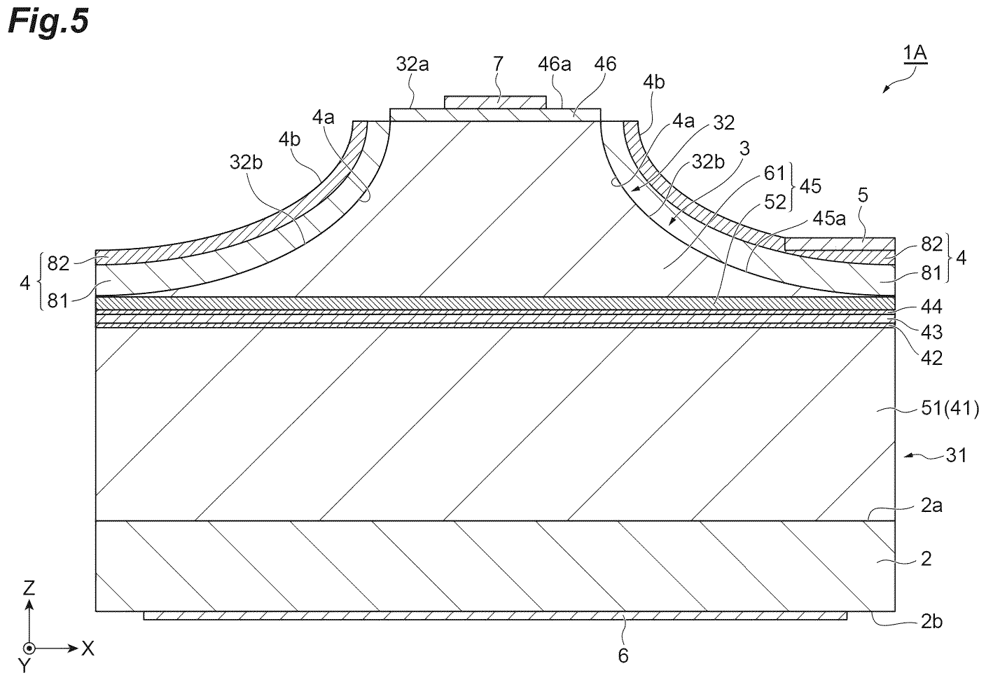

FIG. 5 is a view illustrating a semiconductor laser 1A according to a second embodiment. As compared with the semiconductor laser 1 according to the first embodiment, the semiconductor laser 1A is different from the semiconductor laser 1 in that the first cladding layer 41 does not include the p-type cladding layer 52, and the second cladding layer 45 includes the p-type cladding layer 52. That is, in the semiconductor laser 1A, the second cladding layer 45 between the first cladding layer 41 and the second cladding layer 45 is the one cladding layer that includes the p-type cladding layer 52, and the first cladding layer 41 is the other cladding layer that does not include the p-type cladding layer.

The first cladding layer 41 includes only the n-type cladding layer 51. The n-type cladding layer 51 (that is, the first cladding layer 41) is joined to the semiconductor substrate 2 and the guide layer 42. The guide layer 42 is joined to the n-type cladding layer 51 and the active layer 43. The second cladding layer 45 includes the p-type cladding layer 52 and the n-type cladding layer 61 sequentially laminated on the guide layer 44. The p-type cladding layer 52 is joined to the guide layer 44 and the n-type cladding layer 61.

In this case, the base portion 31 of the semiconductor lamination portion 3 includes the n-type cladding layer 51, the guide layer 42, the active layer 43, the guide layer 44, and the p-type cladding layer 52, and the mesa portion 32 includes the n-type cladding layer 61 and the contact layer 46. In addition, the n-type cladding layer 51, the guide layer 42, the active layer 43, the guide layer 44, and the p-type cladding layer 52 do not include the side surface 32b of the mesa portion 32, and the n-type cladding layer 61 includes the side surface 32b. The p-type burying layer 4 is in contact with the p-type cladding layer 52 in a direction intersecting the lamination direction in the semiconductor lamination portion 3.

The first electrode 5 is provided on the surface 4b of the second burying layer 82 of the p-type burying layer 4. That is, the first electrode 5 is provided on the surface 4b of the p-type burying layer 4 on a side opposite to the semiconductor substrate 2. The second electrode 6 is provided on the rear surface 2b of the semiconductor substrate 2. The third electrode 7 is provided on the surface 46a of the contact layer 46.

According to the semiconductor laser 1A according to the second embodiment described above, the optical absorption can also be suppressed while enabling the optical confinement as in the semiconductor laser 1 according to the first embodiment.

### Third Embodiment

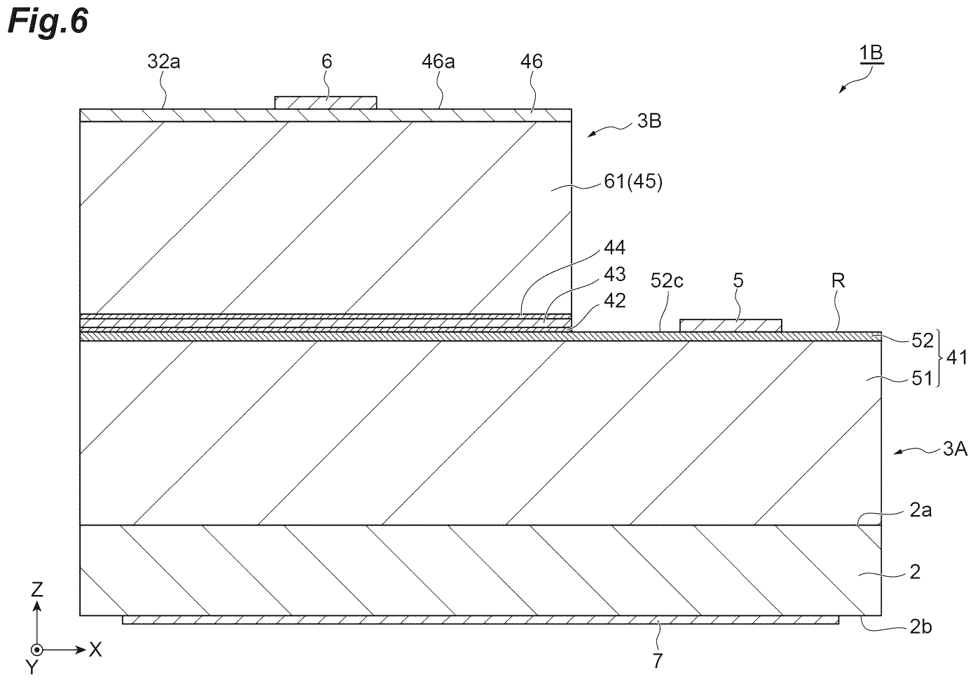

FIG. 6 is a view illustrating a semiconductor laser 1B according to a third embodiment. As compared with the semiconductor laser 1 according to the first embodiment, the semiconductor laser 1B is different from the semiconductor laser 1 in that the base portion 31 and the mesa portion 32 are not provided, the p-type burying layer 4 is not provided, and a surface 52c of the p-type cladding layer 52 on a side opposite to the semiconductor substrate 2 includes an exposed region R that is exposed from the semiconductor lamination portion 3.

More specifically, in the semiconductor laser 1B, the semiconductor lamination portion 3 includes a first lamination portion 3A and a second lamination portion 3B. The first lamination portion 3A includes the first cladding layer 41 (here, consists of the first cladding layer 41) laminated on the front surface 2a of the semiconductor substrate 2. The first cladding layer 41 includes the p-type cladding layer 52. The second lamination portion 3B is formed on a partial region of the first lamination portion 3A. The second lamination portion 3B includes the guide layer 42, the active layer 43, the guide layer 44, the second cladding layer 45, and the contact layer 46 sequentially laminated on the first cladding layer 41.

The second cladding layer 45 does not include a p-type cladding layer. That is, in the semiconductor laser 1B, the first cladding layer 41 between the first cladding layer 41 and the second cladding layer 45 is the one cladding layer including the p-type cladding layer 52, and the second cladding layer 45 is the other cladding layer that does not include the p-type cladding layer.

A region of the first lamination portion 3A other than the region in which the second lamination portion 3B is provided is exposed from the semiconductor lamination portion 3. As a result, in the semiconductor laser 1B, the surface 52c of the p-type cladding layer 52 on a side opposite to the semiconductor substrate 2 includes the exposed region R that is exposed from the semiconductor lamination portion 3. The first electrode 5 is provided in the exposed region R and is in contact with the p-type cladding layer 52.

According to the semiconductor laser 1B according to the third embodiment described above, the optical absorption can also be suppressed while enabling the optical confinement as in the semiconductor laser 1 according to the first embodiment. In addition, in the semiconductor laser 1B according to the third embodiment, for example, the configuration of the semiconductor laser is more simplified and the semiconductor laser can be more easily formed as compared with a case where the p-type burying layer 4 is formed, and the first electrode 5 is provided in the p-type burying layer 4 as in the semiconductor lasers 1 and 1A according to the first embodiment and the second embodiment.

### Fourth Embodiment

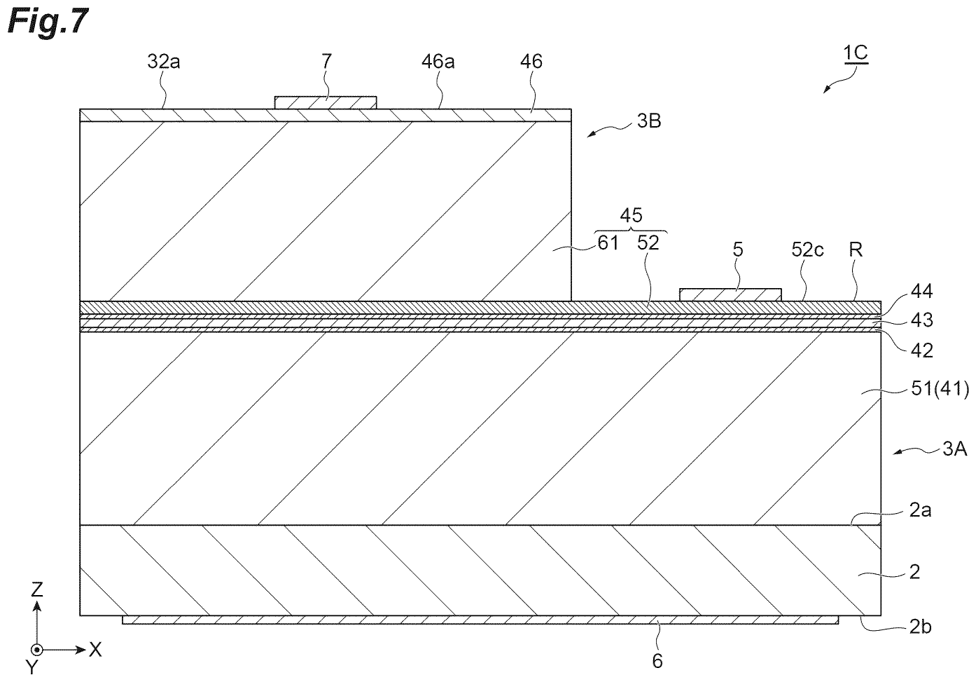

FIG. 7 is a view illustrating a semiconductor laser 1C according to a fourth embodiment. As compared with the semiconductor laser 1B according to the third embodiment, the semiconductor laser 1C is different from the semiconductor laser 1B in that the first cladding layer 41 does not include the p-type cladding layer 52, and the second cladding layer 45 includes the p-type cladding layer 52. That is, in the semiconductor laser 1C, the second cladding layer 45 between the first cladding layer 41 and the second cladding layer 45 is the one cladding layer that includes the p-type cladding layer 52, and the first cladding layer 41 is the other cladding layer that does not include the p-type cladding layer.

The first cladding layer 41 includes only the n-type cladding layer 51. The n-type cladding layer 51 (that is, the first cladding layer 41) is joined to the semiconductor substrate 2 and the guide layer 42. The guide layer 42 is joined to the n-type cladding layer 51 and the active layer 43. The second cladding layer 45 includes the p-type cladding layer 52 and the n-type cladding layer 61 sequentially laminated on the guide layer 44. The p-type cladding layer 52 is joined to the guide layer 44 and the n-type cladding layer 61.

In this case, a first lamination portion 3A of the semiconductor lamination portion 3 includes the n-type cladding layer 51, the guide layer 42, the active layer 43, the guide layer 44, and the p-type cladding layer 52 sequentially laminated on the front surface 2a of the semiconductor substrate 2. The second lamination portion 3B includes the n-type cladding layer 61 and the contact layer 46 sequentially laminated on the p-type cladding layer 52.

A region of the first lamination portion 3A other than the region in which the second lamination portion 3B is provided is exposed from the semiconductor lamination portion 3. As a result, in the semiconductor laser 1B, the surface 52c of the p-type cladding layer 52 on a side opposite to the semiconductor substrate 2 includes the exposed region R that is exposed from the semiconductor lamination portion 3. The first electrode 5 is provided in the exposed region R and is in contact with the p-type cladding layer 52. The second electrode 6 is provided on the rear surface 2b of the semiconductor substrate 2. The third electrode 7 is provided on the surface 46a of the contact layer 46.

According to the semiconductor laser 1C according to the fourth embodiment described above, the optical absorption can also be suppressed while enabling the optical confinement as in the semiconductor laser 1 according to the first embodiment. In addition, in the semiconductor laser 1C according to the fourth embodiment, for example, the configuration of the semiconductor laser is more simplified and the semiconductor laser can be more easily formed as compared with a case where the p-type burying layer 4 is formed, and the first electrode 5 is provided in the p-type burying layer 4 as in the semiconductor lasers 1 and 1A according to the first embodiment and the second embodiment.

### Fifth Embodiment

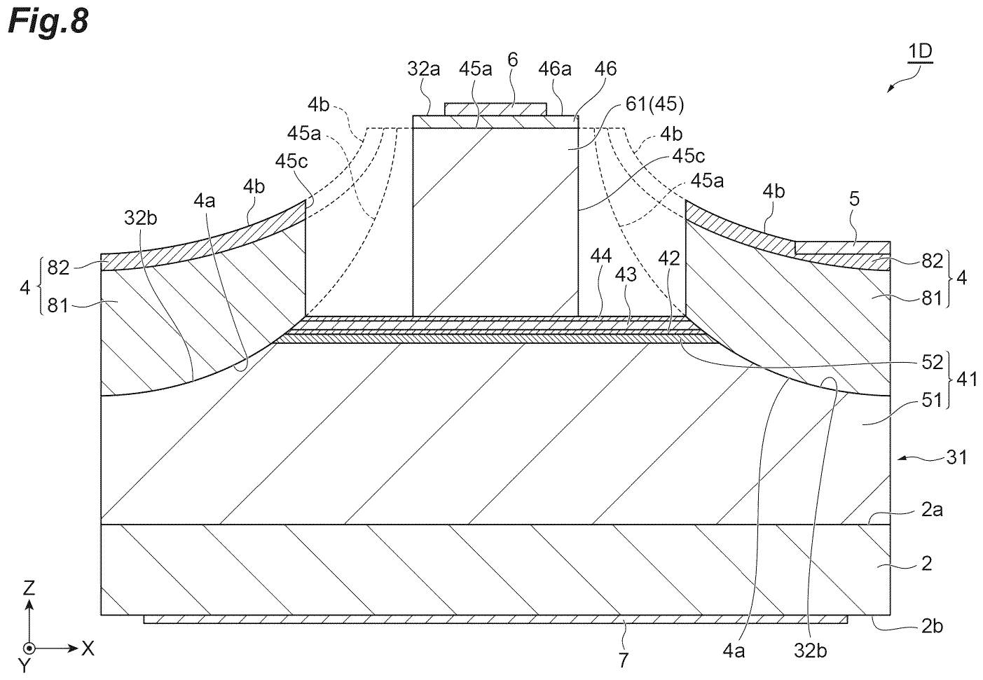

FIG. 8 is a view illustrating a semiconductor laser 1D according to a fifth embodiment. As compared with the semiconductor laser 1 according to the first embodiment, the semiconductor laser 1D is different from the semiconductor laser 1 in that a groove 45c is formed in the second cladding layer 45.

The groove 45c is formed in the surface 45a of the second cladding layer 45 on a side opposite to the active layer 43, and the surface 4a of the p-type burying layer 4. The groove 45c is recessed toward the active layer 43. In the example shown in the drawing, the groove 45c may be provided to reach the guide layer 44 or may not reach the guide layer 44 (that is, the n-type cladding layer 61 may remain). The groove 45c can be formed, for example, by etching. For example, the semiconductor laser 1D can be formed by forming the groove 45c at a position including a surface, which is in contact with the p-type burying layer 4, in the surface 45a of the second cladding layer 45 in the semiconductor laser 1 according to the first embodiment.

According to the semiconductor laser 1D according to the fifth embodiment described above, the optical absorption can also be suppressed while enabling the optical confinement as in the semiconductor laser 1 according to the first embodiment. In addition, according to the semiconductor laser 1D, it is possible to reduce a contact area between the p-type burying layer 4 and the second cladding layer 45 as compared with a case where the p-type burying layer 4 is formed across the surface 45a of the second cladding layer 45 as in the semiconductor laser 1 according to the first embodiment. According to this, a leakage current can be suppressed by narrowing a current path from the p-type burying layer 4 in the second cladding layer 45.

### Sixth Embodiment

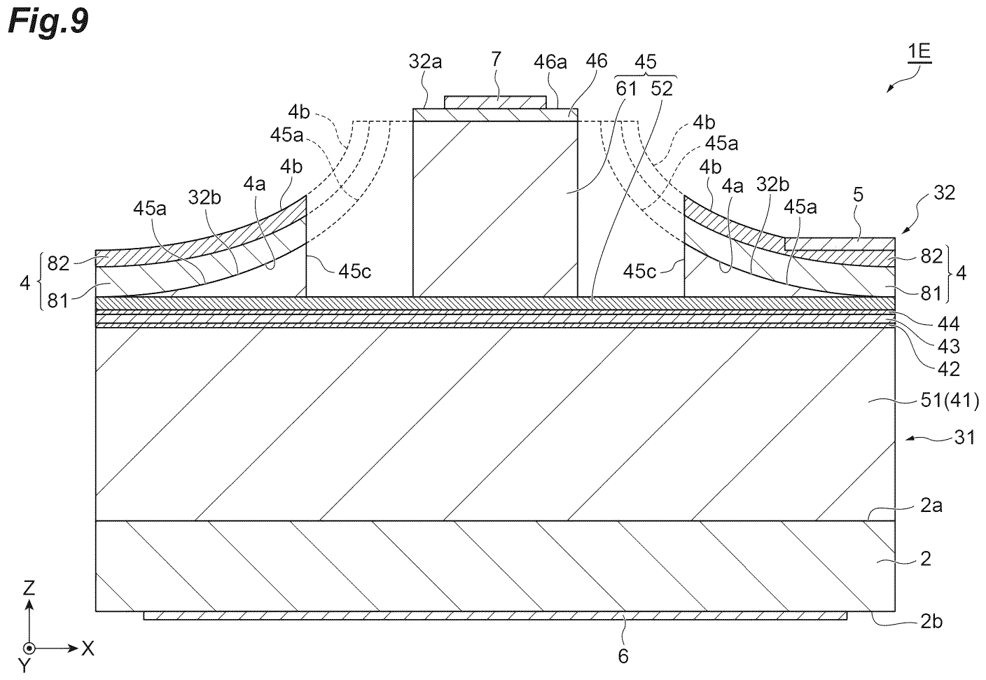

FIG. 9 is a view illustrating a semiconductor laser 1E according to a sixth embodiment. As compared with the semiconductor laser 1A according to the second embodiment, the semiconductor laser 1E is different from the semiconductor laser 1A in that the groove 45c is formed in the second cladding layer 45.

The groove 45c is formed in the surface 45a of the second cladding layer 45 on a side opposite to the active layer 43, and the surface 4a of the p-type burying layer 4. The groove 45c is recessed toward the active layer 43. In the example shown in the drawing, the groove 45c may be provided to reach the p-type cladding layer 52, or may not reach the p-type cladding layer 52 (that is, the n-type cladding layer 61 may remain). The groove 45c is formed, for example, by etching. For example, the semiconductor laser 1E can be formed by forming the groove 45c at a position including a surface, which is in contact with the p-type burying layer 4, in the surface 45a of the second cladding layer 45 in the semiconductor laser 1A according to the second embodiment.

Even in the semiconductor laser 1E according to the sixth embodiment, the optical absorption can also be suppressed while enabling the optical confinement as in the semiconductor laser 1A according to the second embodiment. In addition, according to the semiconductor laser 1E, it is possible to reduce a contact area between the p-type burying layer 4 and the second cladding layer 45 as compared with a case where the p-type burying layer 4 is formed across the surface 45a of the second cladding layer 45 as in the semiconductor laser 1A according to the second embodiment. According to this, a leakage current can be suppressed by narrowing a current path from the p-type burying layer 4 in the second cladding layer 45.

### Modification Example

The present disclosure is not limited to the above-described embodiments and modification examples. For example, materials and shapes of respective configurations are not limited to the above-described materials and shapes, and various materials and shapes can be employed. For example, the semiconductor substrate 2 may not be the n-type semiconductor, and may be a p-type semiconductor or a semi-insulating semiconductor. The semiconductor lasers 1, and 1A to 1D may not be provided with the third electrode 7. The thickness of the p-type cladding layer 52 may not be ½ or less of the thickness of the n-type cladding layer 51 in the first cladding layer 41.

A carrier blocking layer formed from a material having a potential capable of forming a high band offset with the guide layer 42 may be provided between the first cladding layer 41 and the guide layer 42. In addition, a carrier blocking layer formed from a material having a potential capable of forming a high band offset with the guide layer 44 may be provided between the second cladding layer 45 and the guide layer 44.

A non-doped semiconductor layer may be formed between the n-type cladding layer in one cladding layer of the first cladding layer 41 and the second cladding layer 45, and the p-type cladding layer 52 (for example, between the n-type cladding layer 51 and the p-type cladding layer 52 in the first embodiment). In this case, the pn junction formed between the n-type cladding layer and the p-type cladding layer 52 may be formed by laminating the n-type cladding layer and the p-type cladding layer 52 via the non-doped semiconductor layer. In addition, an n-type semiconductor that does not function as a cladding layer may be formed between the n-type cladding layer in the one cladding layer and the p-type cladding layer 52. In this case, the pn junction is formed between the p-type cladding layer 52 and the n-type cladding layer in the one cladding layer by forming the pn junction between the p-type cladding layer 52 and the n-type semiconductor. Even in this case, the thickness of the p-type cladding layer 52 is larger than the thickness of the portion, which is formed inside the p-type cladding layer 52, in the depletion layer formed due to the pn junction. In addition, a p-type semiconductor that does not function as a cladding layer may be formed between the n-type cladding layer and the p-type cladding layer 52 in the one cladding layer. In this case, since the pn junction is formed between the n-type cladding layer and the p-type semiconductor, the pn junction is formed between the n-type cladding layer in the one cladding layer and the p-type cladding layer 52. Even in this case, the thickness of the p-type cladding layer 52 is larger than the thickness of the portion, which is formed inside the p-type cladding layer 52, in the depletion layer formed due to the pn junction.

The well layer of the active layer 43 may contain, for example, In₁₋ₓ₃Gaₓ₃AS_{y3}P_{1-y3} (provided that, 0<x3<1, 0<y3≤1). As an example, the well layer of the active layer 43 may consist of InGaAs and InGaAsP. The barrier layer of the active layer 43 may contain, for example, InGaAsP. In this case, the guide layer 42 and the guide layer 44 may be formed by, for example, a material containing InGaAsP.

The p-type burying layer 4 may not include the second burying layer 82, or may be constituted by only the first burying layer 81. Even in this case, the heat dissipation property can be improved as in the case where the second burying layer 82 is provided. In addition, in a case where the p-type burying layer 4 is constituted by only the first burying layer 81, the first burying layer 81 may not contain InP, and may contain InGaAs. In this case, it is possible to suppress the material of the first electrode 5 from diffusing to the p-type burying layer 4 and it is possible to further suppress an increase in a resistance value of a current as compared with a case where the p-type burying layer 4 contains InP.

The semiconductor substrate 2 may contain GaAs. In this case, for example, the semiconductor laser emits laser light having a wavelength of approximately 940 nm. In addition, in a case where the semiconductor substrate 2 contain GaAs, the n-type cladding layer 51, the p-type cladding layer 52, the guide layer 42, the guide layer 44, and the n-type cladding layer 61 may contain, for example, AlGaAs. The well layer of the active layer 43 may contain, for example, InGaAs. The barrier layer of the active layer 43 may contain, for example, AlGaAs. The contact layer 46 may contain, for example, GaAs. The first burying layer 81 of the p-type burying layer 4 may contain, for example, AlGaAs. The second burying layer 82 of the p-type burying layer 4 may contain, for example, GaAs.

The side surface 32b of the mesa portion 32 of the semiconductor lamination portion 3 in the first embodiment and the second embodiment may not be curved, and may be formed along the lamination direction of the semiconductor lamination portion 3. In this case, the surface 4b of the p-type burying layer 4 may be a surface on a side opposite to the semiconductor substrate 2, and may not be a surface on a side opposite to the surface 4a that is in contact with the side surface 32b. In addition, in this case, the groove 45c according to the fifth embodiment and the sixth embodiment may be formed in a portion of the surface 45a of the second cladding layer 45 that is along the top surface 32a in the semiconductor lamination portion 3.

What is claimed is:

1. A semiconductor laser, comprising:
a semiconductor substrate;
a semiconductor lamination portion laminated on a surface of the semiconductor substrate; and
a first electrode and a second electrode,
wherein the semiconductor lamination portion includes,
an active layer,
a first cladding layer located on the semiconductor substrate side with respect to the active layer, and
a second cladding layer located on a side opposite to the semiconductor substrate with respect to the active layer,
each of the first cladding layer and the second cladding layer includes an n-type cladding layer,
one cladding layer of the first cladding layer and the second cladding layer further includes a p-type cladding layer located between the n-type cladding layer and the active layer,
the first electrode and the second electrode are electrically connected to each other via the other cladding layer of the first cladding layer and the second cladding layer, the active layer, and the p-type cladding layer, and
the thickness of the p-type cladding layer is smaller than the thickness of the n-type cladding layer in the one cladding layer.

2. The semiconductor laser according to claim 1, further comprising:
a p-type burying layer that is in contact with the p-type cladding layer in a direction intersecting a lamination direction in the semiconductor lamination portion,
wherein the first electrode is provided on a surface of the p-type burying layer on a side opposite to the semiconductor substrate.

3. The semiconductor laser according to claim 2,
wherein a groove recessed toward the active layer is formed in a surface of the second cladding layer on a side opposite to the active layer.

4. The semiconductor laser according to claim 1,
wherein a surface of the p-type cladding layer on a side opposite to the semiconductor substrate includes an exposed region that is exposed from the semiconductor lamination portion, and
the first electrode is provided in the exposed region.

5. The semiconductor laser according to claim 1,
wherein the semiconductor substrate consists of an n-type semiconductor.

6. The semiconductor laser according to claim 1, further comprising:
a third electrode that is electrically connected to the first electrode via the n-type cladding layer in the one cladding layer and the p-type cladding layer.

7. The semiconductor laser according to claim 1,
wherein the thickness of the p-type cladding layer is larger than the thickness of a portion, which is formed inside of the p-type cladding layer, in a depletion layer formed due to a pn junction formed between the n-type cladding layer in the one cladding layer and the p-type cladding layer.

8. The semiconductor laser according to claim 1,
wherein the thickness of the p-type cladding layer is ½ or less of the thickness of the n-type cladding layer in the one cladding layer.

9. The semiconductor laser according to claim 1,
wherein the one cladding layer is a first cladding layer.

10. The semiconductor laser according to claim 1,
wherein the one cladding layer is a second cladding layer.
